(19) United States
(12) Patent Application Publication
(10) Pub. No.: US 2010/0013472 A1
(43) Pub. Date: Jan. 21, 2010

(54) METHOD AND APPARATUS FOR COIL ARRAY COMPRESSION

(76) Inventors: Martin Buehrer, Schaffhausen (CH); Klaas Pruessmann, Zurich (CH); Sebastian Kozerke, Hedingen (CH)

Correspondence Address: MCCORMICK, PAULDING & HUBER LLP, CITY PLACE II, 185 ASYLUM STREET, HARTFORD, CT, 06103, US

(21) Appl. No.: 12/440,931

(22) PCT Filed: Sep. 10, 2007
(86) PCT No.: PCT/EP2007/007867

§ 371 Date: Jun. 12, 2009

(30) Foreign Application Priority Data
Sep. 13, 2006 (EP) 06019146.7

(51) Int. Cl. G01R 33/48; G01R 33/44

(52) U.S. Cl. 324/307; 324/318

(57) ABSTRACT

A method of processing magnetic resonance imaging signals from a plurality of receiver coils of a magnetic resonance imaging system, comprises the steps of receiving from said plurality of receiver coils a corresponding plurality of original signals in the time-domain forming an n-dimensional signal vector νₖ wherein n is the number of receiver coils; linearly combining said original signals so as to obtain a plurality of transformed signals forming an m-dimensional transformed signal vector ν′ₖ wherein m is smaller than n and wherein said step of linearly combining is represented by a linear transformation matrix A; and reconstructing an image from said plurality of transformed signals. Said transformation matrix A is determined for given sensitivity characteristics and noise statistics of said plurality of receiver coils so as to substantially maximize the signal-to-noise ratio in a preselected image region or volume which is preferably smaller than the imaging slice or volume selected by the magnetic resonance experiment.

### BACKGROUND OF THE INVENTION

The invention relates to magnetic resonance (MR) methods employing multiple receive antennae which are operated in parallel. Such methods are known as phased-array or coil array imaging techniques. With suitable combination of the signals from multiple physical coils, the signal-to-noise ratio (SNR) in the images is improved relative to methods using a single receive coil (U.S. Pat. No. 4,871,969). Further methods which make use of the spatial encoding capabilities of coil arrays to reduce the number of magnetic field gradient-based spatial encoding steps are known as parallel imaging methods (e.g. U.S. Pat. No. 6,326,786 B1). These methods allow speeding up the MR signal collection process for forming images by deliberately undersampling the data space in the Fourier domain of the image.

In aforementioned methods, MR signals are detected by each of the individual antennae in a coil array and processed in parallel by the receiver unit which typically contains means for analog-to-digital conversion of the signals. Thereupon the signals are stored in digital memory until all necessary signals have been acquired to form a composite image. In the composite image, data from all physical coils are combined using a suitable algorithm.

In general, the SNR increases with increasing numbers of coil elements covering the object of interest, and so does the performance of parallel imaging within certain limits governed by electrodynamics (US2005/0179433 A1).

In view of the increasing numbers of coil elements operated in parallel, limitations are faced which relate to processing and storing signals from a large number of independent coil elements. Firstly, in order to operate a large set of independent coils, the receiver of the MR system is required to be equipped with as many receiver units as coil elements contained in the coil array. In general, the number of receiver units is only scalable within certain limits due to hardware constraints as well as cost.

A second limitation arises from storage and processing demands. When operating large coil arrays, all signals necessary for forming an image need to be collected before further processing. This requires considerable digital storage capacity. More important, digital processing for forming images from signals detected with a plurality of coils becomes computationally expensive resulting in long processing times.

Signals from multiple coils may be combined if the coil array exhibits some degree of symmetry and noise eigenvectors with degenerate eigenvalues exist, thus allowing adding the signals from coil elements with identical or similar eigenvalues after applying some phase shift depending on the geometry of the coil array. Such a method and apparatus are known from patent publications US 2003/0038632 A1 and B2. However, the aforementioned method does not take into account the sensitivities of the individual coil elements with respect to the volume-of-interest. For example, an individual coil may be remote to the volume-of-interest and therefore relatively insensitive compared to a coil element close to the volume-of-interest. This insensitivity is not reflected in the coil's noise if the coil is loaded sufficiently. Furthermore, the relative differences in sensitivities among individual coil elements with respect to a volume-of-interest are an important determinant for the performance of parallel imaging and cannot be assessed based on noise information. Also, in practical applications the imaging volume prescribed by an MR method can be considerably smaller than the sensitive volume of the coil array, thus requiring knowledge of the sensitivity of each coil element with respect to the imaging volume. Moreover, in many applications the volume-of-interest may be even smaller than the imaging volume selected by an MR method.

### BRIEF SUMMARY OF THE INVENTION

It is an object of the present invention to address the limitations and shortcomings mentioned above. The above and other objects are achieved by the method defined in claim 1, according to which a method of processing magnetic resonance imaging signals from a plurality of receiver coils of a magnetic resonance imaging system comprises the steps of:
a) receiving from said plurality of receiver coils a corresponding plurality of original signals forming an n-dimensional signal vector, wherein n is the number of receiver coils;
b) linearly combining said original signals so as to obtain a plurality of transformed signals forming an m-dimensional transformed signal vector, wherein m is smaller than n and wherein said step of linearly combining is represented by a linear transformation matrix A; and
c) reconstructing an image from said plurality of transformed signals;
   wherein said transformation matrix A is determined so as to substantially maximize the signal-to-noise ratio in a preselected region of said reconstructed image for given sensitivity characteristics and noise statistics of said plurality of receiver coils.

It shall be understood that the plurality of m transformed signals is equivalent to the output of a reduced number of m virtual receiver coils, i.e. n original receiver coils are mapped onto m virtual receiver coils. Accordingly, the linear transformation can be called a “coil array compression”.

The term “substantially maximizing” shall be understood as an exact or a suitable numeric solution of an extremal problem as further described hereinbelow. Moreover, it shall be understood that practical determination of sensitivity and noise characteristics inevitably has certain limits in its accuracy.

Further aspects of the invention comprise the magnetic resonance imaging system as defined in claim 13 and the computer readable medium as defined in claim 18.

Advantageous embodiments are defined in the dependent claims.

In principle, the sensitivity characteristics and/or the noise statistics could be determined theoretically from the design characteristics of each receiver coil or from a corresponding manufacturer's specification and from the conditions under which each coil is being operated. Advantageously, however, the sensitivity characteristics are determined from calibration measurements carried out with said plurality of receiver coils (claim 2), and the noise statistics are determined from noise data received from said plurality of receiver coils (claim 4).

According to a specific embodiment, the sensitivity characteristics are expressed in terms of sensitivity matrices (claim 3). According to a further embodiment, the noise statistics are expressed in terms of a noise covariance matrix Ψ (claim 5). Moreover, it may be possible to use certain operating conditions wherein there is no correlation of the noise between different coils, in which case said noise covariance matrix Ψ is substantially an identity matrix (claim 6), which leads to a simplification of the extremal problem for A.

According to the invention, the extremal problem is solved for a preselected image region. The preselected image may be substantially equal to an imaging volume as selected by a volume selection method of the magnetic resonance imaging system (claim 7). Preferably, the region- or volume-of-interest will be smaller (claim 8); most notably, it may be e.g. a certain slice or a set of slices within a volume or a region- or volume-of-interest within a slice or volume that encompasses a certain object-of-interest. The terms region-of-interest and volume-of-interest are used interchangeably hereafter.

If the number of virtual coil elements m after coil array compression is greater than one, coil combination algorithms can be used to create a single composite image from m virtual coil images (claim 9). Moreover, for many applications it will be advantageous to apply undersampling. In this case parallel imaging reconstruction is used to create the composite image (claim 10) from the virtual coil images.

As it is well-known, an analog-to-digital conversion step is generally applied to the signals obtained from magnetic resonance imaging receiver coils, which is achieved by means of so-called “Receiver and A/D-Converter” devices. In the context of the present invention, such analog-to-digital conversion may be applied either to said original signals prior to linear combination thereof (claim 11) or to said transformed signals (claim 12). According to the first variant, the linear combination step is carried out with a digitized version of the original signals; this will generally provide a higher accuracy and a greater adaptability of the linear combination step, but it requires a receiver and A/D-converter device for each one of said n receiver coils (claim 14). According to the second variant, the linear combination step is carried out with the non-digitized original steps; this will require installation of suitable analog circuitry for linear combination, but it allows to reduce the number of receiver and A/D-converter devices from n to m (claim 15).

Advantageously, the means for linearly combining the original signals are adjustable, so as to allow adaptation of the image acquisition operating conditions (claim 16). This is particularly useful if the system further comprises means for measuring the sensitivity characteristics and the noise statistics (claim 17).

### BRIEF DESCRIPTION OF THE DRAWINGS

The above mentioned and other features and objects of this invention and the manner of achieving them will become more apparent and this invention itself will be better understood by reference to the following description of various embodiments of this invention taken in conjunction with the accompanying drawings, wherein:

FIG. 1 shows a schematic drawing of the signal receive and reconstruction process wherein the sampled signals from all physical coils (stored in vector ν_{K}) are combined in the time-domain using the linear combination A passing a reduced virtual set, consisting of m virtual coils, to the reconstructor unit which transforms the signals from the time-domain to the image-domain by using the Fourier transformation F;

FIG. 2 shows an illustration of the desired region-of-interest (ROI) with and without undersampling, with pixel ρ in the folded ROI (ROI_{folded}) being the superposition of pixel values p₁, p₂, p₃ in the unfolded ROI;

FIG. 3 shows a computer model of a sphere surrounded by a coil array with 32 independent coil elements with the central slice being the ROI;

FIG. 4 shows the central slice of the computer model of a sphere and total image noise maps reconstructed from compressed coil array data consisting of different output channels m without and with 4-fold parallel imaging (SENSE);

FIG. 5 shows normalized SNR averaged across the ROI as function of the number of virtual coil elements m for the computer model without and with 4-fold SENSE;

FIG. 6 shows selected heart phase images from a cardiac cine acquisition and total image noise maps reconstructed from compressed coil array data consisting of different output channels m without and with 2-fold SENSE and with the region-of-interest (ROI) marked with the dotted line;

FIG. 7 shows the performance of array compression expressed as the inverse of relative noise amplification as a function of the size of the ROI for the optimized combination as proposed herein relative to a method using Principal Component Analysis (PCA) to reduce the number of virtual coils m.

FIG. 8 shows a preferred embodiment in which n physical coils are compressed to m virtual coils prior to the receiver units including analog-to-digital conversion;

FIG. 9 shows a preferred embodiment in which n physical coils are compressed to m virtual coils after the receiver unit; and

FIG. 10 shows the schematic of an apparatus for MR imaging according to the invention.

### DETAILED DESCRIPTION OF THE INVENTION

The exemplifications set out herein are not to be construed as limiting the scope of this disclosure or the scope of this invention in any manner.

The subject invention relates to a method and apparatus for combining signals from multiple coil elements which are operated in parallel based on knowledge of the sensitivities of the individual coil elements with respect to a volume-of-interest which is preferably smaller than the imaging volume selected by the MR experiment.

In detail, the sampled signals from n physical coils (stored in vector ν_{K}) are combined in the time-domain using linear combination A creating a reduced set of m virtual coils contained in vector ν′_{K} under the constraint that the signal-to-noise ratio in the reconstructed image within the volume-of-interest is maximized:

i′_{ê}=Ai_{ê} [1]

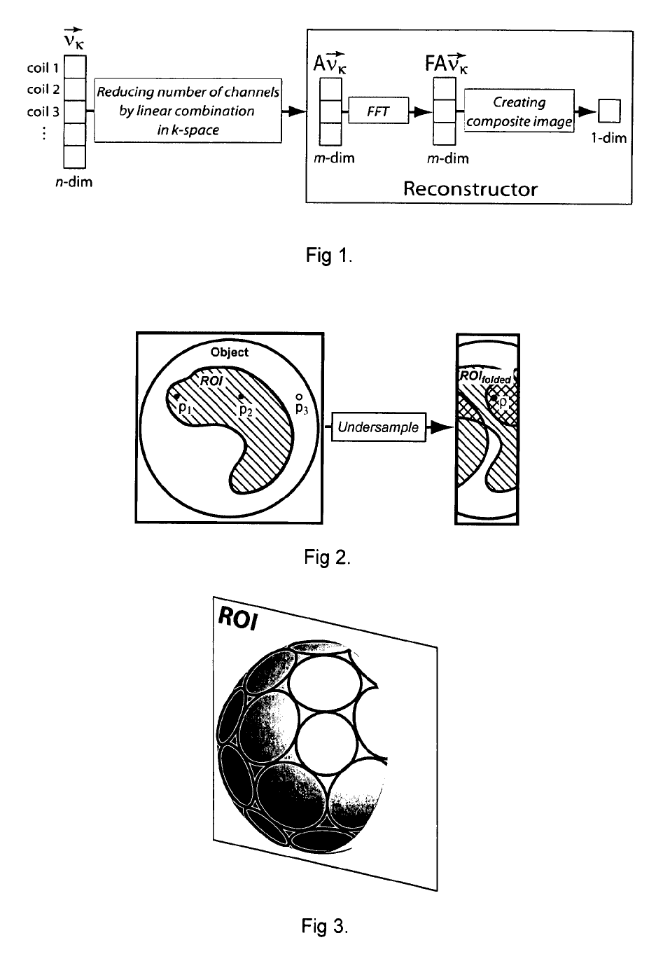

The MR signals from the m virtual coils are passed on to the reconstructor unit for image reconstruction purposes (FIG. 1). The Fourier transformation F and the subsequent combination of the m coil images is done using standard methods (e.g. SoS) or reconstruction methods known for parallel imaging (e.g. SENSE). The compression factor n/m is adjustable but typically dependent on the embodiment as detailed below.

The transformation matrix A has to be chosen such that the signal-to-noise ratio in the volume- or region-of-interest of the reconstructed image is maximized. When using parallel imaging with SENSE a given undersampling factor R creates a folded region-of-interest ROI_{folded} consisting of superimposed pixels ρ receiving signal contributions from R locations of the object (FIG. 2). The image noise after SENSE reconstruction in the unfolded pixels of ρ can then be expressed as the diagonal elements of the image noise matrix:

X_{ρ}=(S_{ρ}^{H}Ψ⁻¹S_{ρ})⁻¹ [2]

where S_{ρ} denote the complex coil sensitivities from all coils and locations superimposed in pixel ρ. The superscript ^{H} denotes conjugate transpose. The receiver noise covariance matrix is Ψ. If the undersampling factor R is set to one, the data are not undersampled and hence no fold-over is introduced. In this case ROI_{folded} is equal to ROI. For simplicity ROI_{folded} is used to denote the region-of-interest for both, the situation with R equal to one and the situation with R being greater than one.

By applying a linear transformation A the sensitivity matrix S_{ρ} and the noise covariance matrix Ψ are transformed to:

S′_{ρ}=AS_{ρ}

Ψ′=AΨA^{H} [3]

The noise matrix in the unfolded pixels of ρ upon transformation A is:

X′_{ρ}=(S_{ρ}^{H}A^{H}(AΨA^{H})⁻¹AS_{ρ})⁻¹ [4]

Since image quality is optimized in a limited region which is equal to ROI, a filter F_{ρ} is defined selecting only the diagonal elements of X′_{ρ} corresponding to pixels inside the ROI. Minimization of the root-mean-square noise in the region-of-interest can now be expressed as minimizing the sum of traces of the transformed and filtered noise matrices X′_{ρ} in all pixels ρ of the region ROI_{folded}:

$$\begin{matrix}{\sum }_{ρ ∈ {ROI}_{folded}} Tr ( {F}_{ρ} {X}_{ρ}^{′} ) = {\sum }_{ρ ∈ {ROI}_{folded}} Tr [ {{F}_{ρ} ( {S}_{ρ}^{H} {{A}^{H} ( A Ψ {A}^{H} )}^{- 1} {AS}_{ρ} )}^{- 1} ] \\ {=}^{!} min\end{matrix} \qquad [ 5 ]$$

AΨA^{H} can be seen as the noise covariance matrix obtained from a virtual set of m coils after transformation A. Without restrictions to the solution we can demand orthogonality between the m coils: AΨA^{H}=id. This may be expressed by defining a transformation T which transforms the noise covariance matrix into identity: \hat{Ψ}=TΨT^{H}=id. The sensitivities upon transformation T become Ŝ_{ρ}=TS_{ρ} and A modifies to A→Â. Postulating orthogonality between the m virtual coil elements translates into the constraint for Â to be unitary, i.e. ÂÂ^{H}=id. Accordingly, the above expression modifies to:

$${\sum }_{ρ ∈ {ROI}_{folded}} Tr [ {{F}_{ρ} ( {\hat{S}}_{ρ}^{H} {\hat{A}}^{H} {\hat{A}}^{H} \hat{A} {\hat{S}}_{ρ} )}^{- 1} ] {=}^{!} min \\ s . t . \hat{A} {\hat{A}}^{H} = id \qquad [ 6 ]$$

The solution to the expression above is optimal according to the requirement for a minimal root-mean-square of the noise, however it is computationally demanding.

In a practical setting an approximate solution to equation [6] may be found as described below.

### Approximate Solution

To avoid computationally intensive numerical methods the minimization problem above may be simplified using appropriate approximations. Aim of the approximation is to avoid the matrix inversion in [6] which converts the minimization problem into a maximization problem while avoiding singular summands. Such an approximation may be derived as follows:

$$B = {\sum }_{ρ ∈ {ROI}_{folded}} {\hat{S}}_{ρ} {\hat{S}}_{ρ}^{†} \qquad [ 7 ]$$

An optimized transformation A is then obtained according to:

A=CU^{H}T [8]

where the unitary matrix U is defined by the singular value decomposition of B, such that B=UFU^{H}. Matrix C=(id|0)selects the first m rows of the unitary matrix U^{H}. Accordingly, the transformation A then maximizes the squared length of the rotated and projected basis in the m-dimensional subspace summed over all pixels in the ROI. As such, transformation A approximates the requirement for minimal total image noise as given above. The fact that all pixels are treated identically results in homogenous sensitivity maps where all pixels in the ROI have non-zero sensitivity values.

The formalism above is converted into following exemplary procedural steps in a practical setting in which, for simplicity, no undersampling (i.e. R=1) is applied:
1. Determination of coil sensitivity maps for all physical coils of the array from a calibration measurement. These sensitivity maps are referred to as sensitivity input data. The calibration measurement can be a fast low flip angle gradient echo sequence.
2. Calculation of the noise covariance matrix v based on noise data received from each of the physical coil elements. The noise data may be measured by e.g. a zero flip angle calibration measurement. In case noise data are not available Ψ is set to the identity matrix.
3. Specification of a region-of-interest as given by a contour drawn around the object-of-interest by the user on a survey image.
4. Population of the sensitivity matrix S_{ρ} with sensitivity input data from all pixel locations ρ within the region-of-interest (ROI). Noise decorrelation of the sensitivity input data using Ψ. This step results in a modified sensitivity matrix S_{ρ}→Ŝ_{ρ}.
5. Solving the minimization problem by approximating the optimal solution using a singular value decomposition method according to equation [8].
6. Multiplication of the MR input signals contained in ν_{K} with resulting matrix A to obtain reduced set of signals in ν′_{K}.
7. Image reconstruction using standard reconstruction algorithms (e.g. sum-of-squares reconstruction).

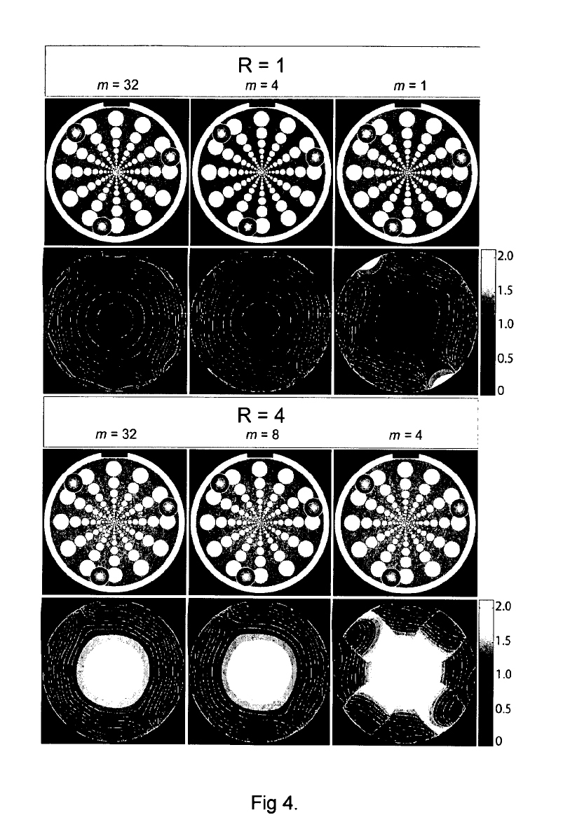

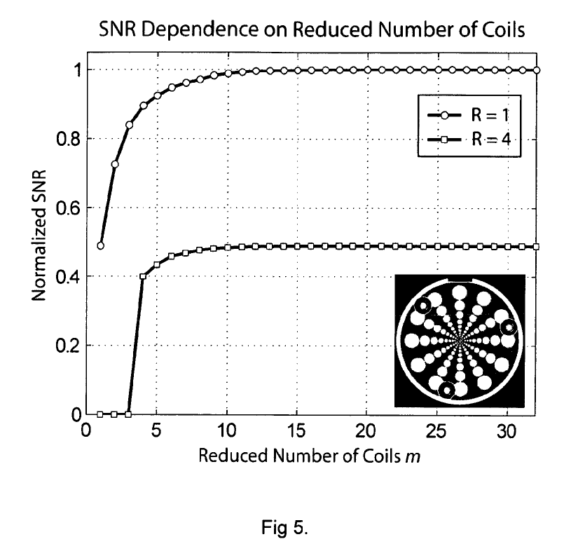

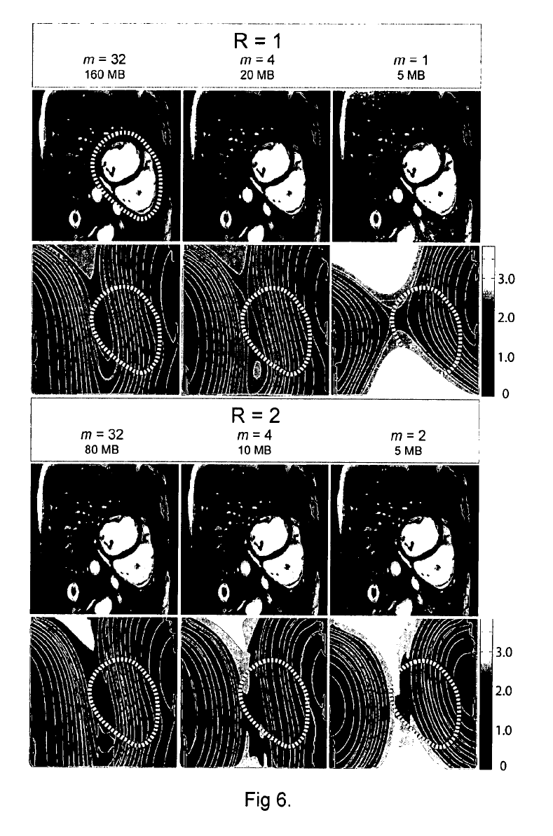

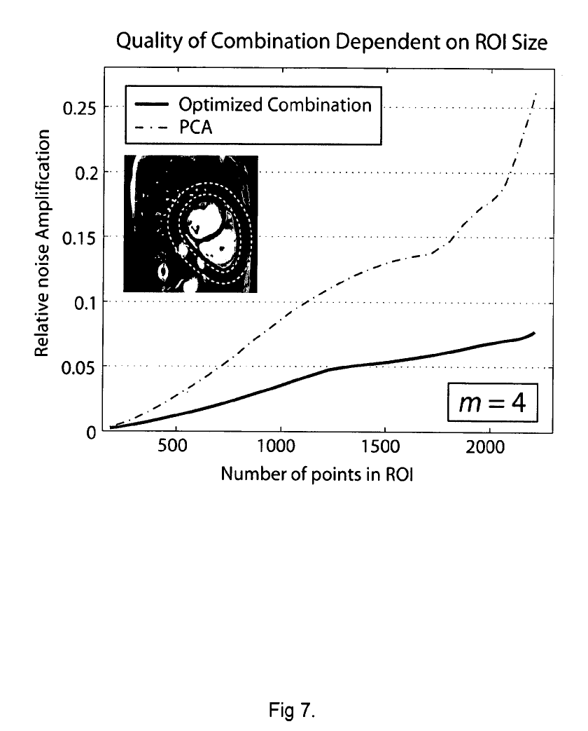

In an exemplification of the methods described above, a computer model of a spherical object surrounded by thirty-two identical surface coils (n=32) is shown (FIG. 3) with the region-of-interest (ROI) marked. Images and noise maps reconstructed from fully sampled data (R=1) and 4-fold undersampled data (R=4) for different compression factors n/m are compiled in FIG. 4. The dependency of the signal-to-noise ratio within the region-of-interest of the reconstructed images as a function of the number of virtual coils m is shown in FIG. 5. Selected image frames and corresponding noise maps from a cine series of the heart acquired in a human subject and reconstructed with different numbers of virtual coils are shown in FIG. 6. Finally, the performance of array compression expressed as the inverse of relative noise amplification as a function of the size of the ROI using the method proposed herein (denoted optimized combination) is shown in FIG. 7 with n=32 and m=4. For reference, the result of the optimized combination is compared to a standard method commonly used to reduce the dimensionality of a problem known as Principal Component Analysis (PCA). According to FIG. 7 the performance of coil array compression is best when the region-of-interest is small thus tightly capturing the object-of-interest (in this case the heart) and if the optimized combination as proposed is used.

In a variant of the invention the sensitivity information of each coil element is obtained from a calibration scan and subsequent division of each coil image by the image obtained from a homogenous volume coil. Alternatively, sensitivity information is derived without using a volume coil image by dividing individual coil images by their sum-of-squares (SoS) image.

In another variant of the invention the sensitivity information is derived from simulated sensitivity data or other prior knowledge making a calibration measurement unnecessary.

A variant of the invention uses the imaging volume selected by the MR method as the volume- or region-of-interest.

In a particularly preferred variant the volume- or region-of-interest is defined by the user to encompass the object of interest which can occupy a smaller volume than that selected by the MR method.

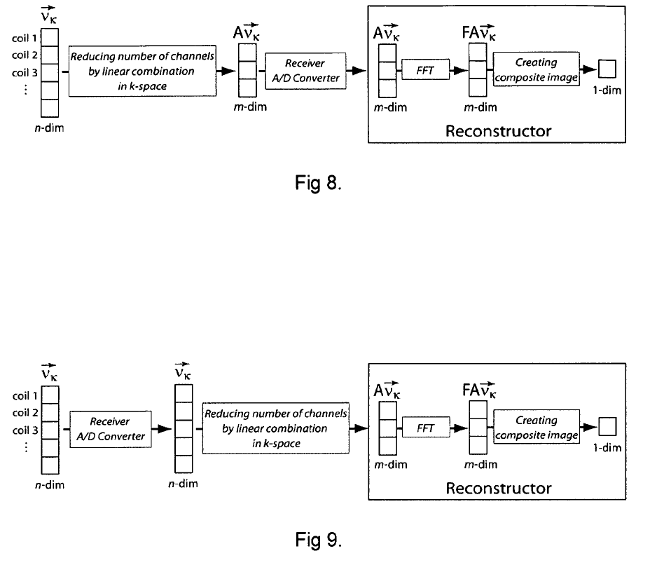

In a preferred embodiment of the method described above, a coil array with more coil elements than receiver units available in the MR system is operated (FIG. 8). This requires combination of coil signals prior to the receiver by analog hardware. Analog hardware makes use of appropriate amplitude and phase splitters to realize the linear transformation described by matrix A. The sensitivity information from all physical coil elements can then be obtained in a sequential fashion during the calibration scan by sequentially connecting subsets of physical coils to the available receive channels. The compression factor in such an embodiment is equal to or greater than the ratio of independent coil elements over the number of available receivers.

In another embodiment, the MR signals from n physical coils are digitized prior to application of the transformation matrix A (FIG. 9). Digitization of the MR signal may either be directly on the coil elements by suitable analog-to-digital conversion hardware or in the receiver unit to which the coils are connected. This assumes a corresponding number of n receivers available simultaneously. In such an embodiment, the compression factor depends on performance requirements in the reconstruction unit. Such a requirement may be related to limits on storage capacity or demand on minimum reconstruction speed or both.

The functions of a magnetic resonance imaging system according to the invention are preferably carried out by means of analog amplitude attenuators and phase shifters or a suitably programmable computer or (micro)processor or by means of a special purpose processor provided with integrated electronic or opto-electronic circuits especially designed for the execution of the methods according to the invention.

For example, a magnetic resonance imaging system according to the invention is a magnetic resonance imaging system whose computer is loaded with a computer program according to the invention. Such a computer program can be stored on a carrier such as a CD-ROM. The computer program is then loaded into the computer by reading the computer program from the carrier, for example by means of a CD-ROM player, and by storing the computer program in the memory of the computer of the magnetic resonance imaging system.

The features mentioned above and below can be used with the invention either individually or collectively in any arbitrary combination. The embodiments shown and described are not to be understood as exhaustive enumeration but rather have exemplary character for describing the invention.

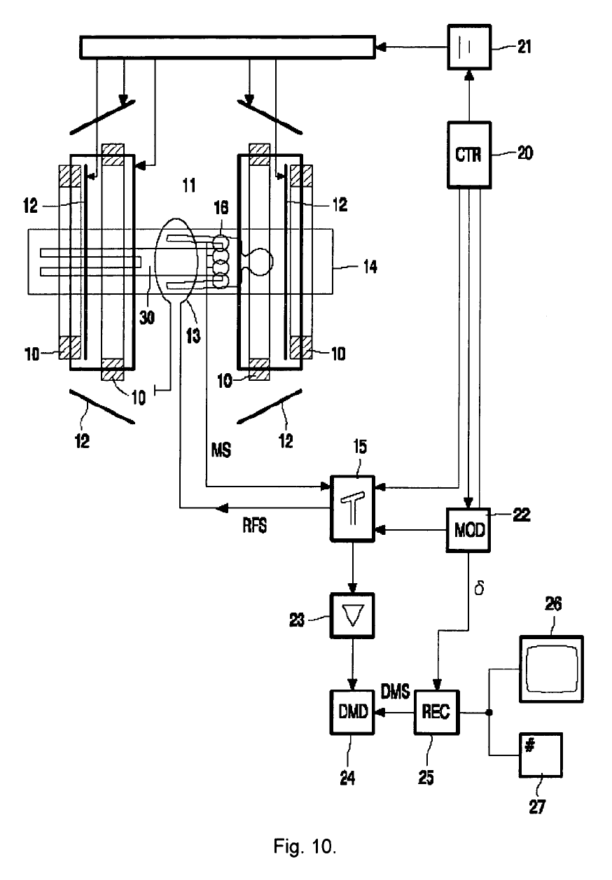

The nuclear magnetic resonance imaging system shown in FIG. 10 includes a set of main coils 10 whereby a steady, spatially uniform magnetic field is generated. The main coils are constructed, for example, in such a manner that they enclose a tunnel-shaped examination space. A patient to be examined is slid on a table into this tunnel-shaped examination space.

The magnetic resonance imaging system also includes a number of gradient coils 12, whereby magnetic fields exhibiting spatial variations, notably in the form of temporary gradients in individual directions, are generated so as to be superposed on the uniform magnetic field. The gradient coils 12 are connected to a controllable power supply unit 21. The gradient coils 12 are energized by application of an electric current by means of the power supply unit 21. The strength, direction and duration of the gradients are controlled by control of the power supply unit.

The magnetic resonance imaging system further includes transmission coils 13 and receiving coils 16 for generating RF excitation pulses and for picking up the magnetic resonance signals, respectively. The transmission coil 13 is preferably constructed as a body coil whereby (a part of) the object to be examined can be enclosed. The body coil is usually arranged in the magnetic resonance imaging system in such a manner that the patient 30 to be examined, being arranged in the magnetic resonance imaging system, is enclosed by the body coil 13. The body coil 13 acts as a transmission aerial for the transmission of the RF excitation pulses and RF refocusing pulses. Preferably, the body coil 13 involves a spatially uniform intensity distribution of the transmitted RF pulses. The receiving coils 16 are preferably surface coils that are arranged on or near the body of the patient 30 to be examined. Such surface coils 16 have a high sensitivity for the reception of magnetic resonance signals, which sensitivity is also spatially inhomogeneous. This means that individual surface coils 16 are mainly sensitive for magnetic resonance signals originating from specific directions, i.e. from specific parts of the patient's body. The coil sensitivity profile represents the spatial sensitivity of the set of surface coils.

The receive coils, notably surface coils, are connected to a demodulator 24 and the received magnetic resonance signals (MS) are demodulated by means of the demodulator 24. The demodulated magnetic resonance signals (DMS) are applied to a reconstruction unit 25. The reconstruction unit reconstructs the magnetic resonance image from the demodulated magnetic resonance signals (DMS) and optionally on the basis of the coil sensitivity profile of the set of surface coils. The coil sensitivity profile has been measured in advance and is stored, for example electronically, in a memory unit which is included in the reconstruction unit. The reconstruction unit derives one or more image signals from the demodulated magnetic resonance signals (DMS), which image signals represent one or more, possibly successive magnetic resonance images. This means that the signal levels of the image signal of such a magnetic resonance image represent the brightness values of the relevant magnetic resonance image.

The reconstruction unit 25 is preferably constructed as a digital image processing unit 25 which is programmed so as to reconstruct the magnetic resonance image from the demodulated magnetic resonance signals and optionally on the basis of the coil sensitivity profile. The digital image processing unit 25 is notably programmed so as to execute the reconstruction in conformity with the present invention. The image signal from the reconstruction unit is applied to a monitor 26 so that the monitor can display the image information of the magnetic resonance image (images). It is also possible to store the image signal in a buffer unit 27 while awaiting further processing.

In order to form a magnetic resonance image or a series of successive magnetic resonance images of an object, notably a patient or other body to be examined, the body is exposed to the magnetic field prevailing in the examination space. The steady, uniform magnetic field, i.e. the main field, orients a small excess number of the spins in the body of the patient to be examined in the direction of the main field. This generates a (small) net macroscopic magnetization in the body. These spins are, for example nuclear spins such as of the hydrogen nuclei (protons), but electron spins may also be concerned. The magnetization is locally influenced by application of the gradient fields. For example, the gradient coils 12 apply a selection gradient in order to select a more or less thin slice of the body. Subsequently, the transmission coils apply the RF excitation pulse to the examination space in which the part to be imaged of the patient to be examined is situated. The RF excitation pulse excites the spins in the selected slice, i.e. the net magnetization then performs a precessional motion about the direction of the main field. During this operation those spins are excited which have a Larmor frequency within the frequency band of the RF excitation pulse in the main field. However, it is also very well possible to excite the spins in a part of the body which is much larger man such a thin slice; for example, the spins can be excited in a three-dimensional part which extends substantially in three directions in the body.

After the RF excitation, the spins slowly return to their initial state and the macroscopic magnetization returns to its (thermal) state of equilibrium. The relaxing spins then emit magnetic resonance signals. Because of the application of a read-out gradient and a phase encoding gradient, the magnetic resonance signals have a plurality of frequency components which encode the spatial positions in, for example the selected slice. The k-space is scanned by the magnetic resonance signals by application of the read-out gradients and the phase encoding gradients. The phase encoding gradients may be applied such that they result in the sub-sampling of the k-space, relative to a predetermined spatial resolution of the magnetic resonance image. For example, a number of lines which is too small for the predetermined resolution of the magnetic resonance image, for example only half the number of lines, is scanned in the k-space.

1. A method of processing magnetic resonance imaging signals from a plurality of receiver coils of a magnetic resonance imaging system, comprising the steps of:
a) receiving from said plurality of receiver coils a corresponding plurality of original signals forming n-dimensional signal vector ν_{K} wherein n is the number of receiver coils;
b) linearly combining said original signals so as to obtain a plurality of transformed signals forming an m-dimensional transformed signal vector ν′_{K} wherein m is smaller than n and wherein said step of linearly combining is represented by a linear transformation matrix A; and
c) reconstructing an image from said plurality of transformed signals;
characterized in that said transformation matrix A is determined so as to substantially maximize the signal-to-noise ratio in a preselected region of said reconstructed image for given sensitivity characteristics and noise statistics of said plurality of receiver coils.

2. The method as defined in claim 1, wherein said sensitivity characteristics are determined from calibration measurements carried out with said plurality of receiver coils.

3. The method as defined in claim 1, wherein said sensitivity characteristics are expressed in terms of sensitivity matrices S.

4. The method as defined in claim 1, wherein said noise statistics are determined from noise data received from said plurality of receiver coils.

5. The method as defined in claim 1, wherein said noise statistics are expressed in terms of a noise covariance matrix Ψ.

6. The method as defined in claim 5, wherein said noise covariance matrix Ψ is an identity matrix.

7. The method as defined in claim 1, wherein said preselected image region is substantially equal to an imaging volume as selected by a volume selection method of said magnetic resonance imaging system.

8. The method as defined in claim 1, wherein said preselected image region is smaller than an imaging volume as selected by a volume selection method of said magnetic resonance imaging system.

9. The method as defined in claim 1, wherein coil combination algorithms are used to create a composite image.

10. The method as defined in claim 9, wherein undersampling is applied and parallel imaging reconstruction is used to create the composite image.

11. The method as defined in claim 1, wherein an analog-to-digital conversion is applied to said original signals prior to linear combination thereof.

12. The method as defined in claim 1, wherein an analog-to digital conversion is applied to said transformed signals.

13. A magnetic resonance imaging system comprising:
a) a plurality of n receiver coils;
b) means for linearly combining a plurality of n original signals forming a signal vector ν_{K} received from said receiver coils so as to obtain a plurality of transformed signals forming an m-dimensional transformed signal vector ν′_{K} wherein m is smaller than n and wherein said step of linearly combining is represented by a linear transformation matrix A; and
c) means for reconstructing an image from said plurality of transformed signals;
characterized in that said transformation matrix A substantially maximizes the signal-to-noise ratio in a preselected region of said reconstructed image for given sensitivity and noise characteristics of said plurality of receiver coils.

14. The imaging system as defined in claim 13, further comprising means for analog-to-digital signal conversion, said conversion means being arranged between said receiver coils and said combining means.

15. The imaging system as defined in claim 13, further comprising means for analog-to-digital signal conversion, said conversion means being arranged between said combining means and said image reconstructing means.

16. The imaging system as defined in claim 13, wherein said combining means are adjustable.

17. The imaging system as defined in claim 16, further comprising means for measuring said sensitivity characteristics and said noise statistics.

18. A computer readable medium storing computer executable instructions for controlling a computer system of a magnetic resonance imaging system as defined in claim 16, including:
a) computer executable instructions for calculating said transformation matrix A;
b) computer executable instructions for adjusting said combining means according to said calculated transformation matrix A.
